(19) United States
(12) Patent Application Publication
(10) Pub. No.: US 2022/0396881 A1
(43) Pub. Date: Dec. 15, 2022

(54) METHOD FOR FABRICATING ELECTRONIC COMPONENT

(71) Applicant: C. Uyemura & Co., Ltd., Osaka-shi (JP)

(72) Inventors: Yohei KANEKO, Hirakata-shi (JP); Katsuhisa TANABE, Hirakata-shi (JP); Tsuyoshi MAEDA, Hirakata-shi (JP); Yuhei OGAMI, Hirakata-shi (JP)

(21) Appl. No.: 17/805,988

(22) Filed: Jun. 8, 2022

(30) Foreign Application Priority Data
Jun. 10, 2021 (JP) 2021-097414
Mar. 4, 2022 (JP) 2022-033421

(51) Int. Cl. C23C 18/16; C23C 18/34

(52) U.S. Cl. CPC C23C 18/1651; C23C 18/1637; C23C 18/34; C23C 18/1658

(57) ABSTRACT

A method for fabricating an electronic component includes the steps of: forming a base material layer of, for example, nickel on a base material of copper, copper alloy, aluminium, or aluminium alloy; applying, as a catalyst, one or more metals selected from the group consisting of gold, palladium, platinum, silver, rhodium, cobalt, tin, copper, iridium, osmium, and ruthenium, on the base material layer; and forming a surface layer by an electroless tin plating bath including trivalent titanium as an reducing agent and pyrophosphate salt as a complexing agent. The surface layer has a thickness of 0.5 μm or more.

### CROSS-REFERENCE TO RELATED APPLICATION

This application claims priority to and the benefit of Japanese Patent Application No. 2021-9741 filed on Jun. 10, 2021, and Japanese Patent Application No. 2022-033421 filed on Mar. 4, 2022, the disclosures of which including the specifications, the drawings, and the claims are hereby incorporated by reference in their entireties.

### BACKGROUND

The present disclosure relates to buses for processor-based systems, and more, including a method for fabricating an electronic component.

A Sn film of Tin (Sn) or a Sn alloy is preferable especially as a solder joint. Thus, Sn films have been widely used for electronic components such as printed wiring boards and wafers.

With recent size reduction and miniaturization of electronic components and circuits, some part cannot be plated by electroplating, and thus, electroless plating is mainly employed for Sn films. A displacement type electroless plating bath among electroless plating methods uses displacement precipitation. Thus, formation of a thick plating film requires etching of a large part of an underlying material such as copper, which causes uneven distribution of thickness of the plating film and significant degradation of solder joint properties such as penetration of solder under a solder resist. In addition, dissolution of, for example, the underlying material such as copper causes problems including disconnection of wires and discoloration of the appearance.

To reduce dissolution of the underlying material, a reduction type Sn plating bath is developed for forming a plating film by including a reducing agent such as trivalent titanium and using reduction reaction of the reducing agent. In the case of the Sn plating bath including trivalent titanium as a reducing agent, however, oxidation to tetravalent titanium rapidly progresses so that growth of plating stops, disadvantageously. A method of performing plating while reducing tetravalent titanium to trivalent titanium has been studied, but this method involves easiness of bath decomposition because of poor stability of the plating bath as well as supply of a reducing agent, and it is difficult to form a thick Sn plating film. If the Sn plating film is thin, when a large thermal hysteresis is applied to this film in assembly, the Sn plating film is lost by alloying with an underlying material so that connection reliability decreases.

In another method studied to date, formation of a Sn plating film and formation of copper plating film are alternately repeated to thereby increase the thickness of the Sn plating film (see, for example, Japanese Patent Application Publication No. 2010-202895).

### SUMMARY

Although alternate film formation ensures an increase in thickness of the plating films, since the alternate film formation have to be repeated, the process is complicated.

It is therefore an object of the present disclosure to enable stable fabrication of an electronic component including a sufficiently thick Sn plating film and having high connection reliability.

An aspect of a method for fabricating an electronic component according to the present disclosure includes: a base material layer formation step of forming a base material layer of nickel or a nickel alloy by an electroless nickel plating bath or an electroless nickel alloy plating bath on a substrate of copper, a copper alloy, aluminium, or an aluminium alloy; a catalyst application step of applying, as a catalyst, one or more metals selected from the group consisting of gold, palladium, platinum, silver, rhodium, cobalt, tin, copper, iridium, osmium, and ruthenium, on the base material layer; and a surface layer formation step of forming a surface layer by an electroless tin plating bath or an electroless tin alloy plating bath containing trivalent titanium as a reducing agent and pyrophosphate salt as a complexing agent, wherein in the surface layer formation step, a surface layer with a thickness of 0.5 μm or more is formed. The method for fabricating an electronic component according to the present disclosure enables stable fabrication of an electronic component including a sufficiently thick Sn plating film and having high connection reliability.

### BRIEF DESCRIPTION OF THE DRAWINGS

FIG. 1 is a cross-sectional view illustrating stacked films according to one embodiment.

FIG. 2 is a schematic view illustrating an example of an electroreduction tank.

### DESCRIPTION OF EMBODIMENTS

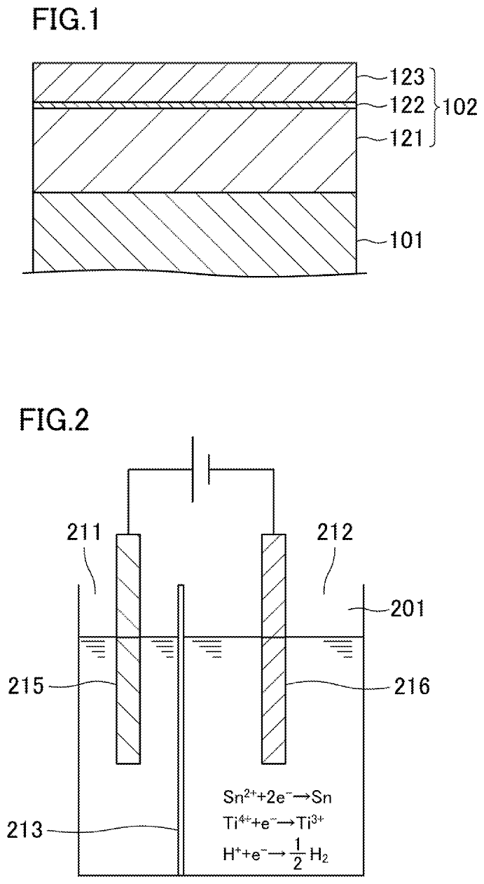

In a method for fabricating an electronic component according to this embodiment, stacked films 102 including a base material layer 121, a catalyst 122, and a surface layer 123 formed on a base material 101 as illustrated in FIG. 1.

The base material 101 may be, for example, an interconnection layer or a connection pad formed on the surface a printed wiring board, a semiconductor wire, or other components. The base material 101 may also be, for example, a metal layer formed by plating, spattering or other processes on the surface of an interconnection layer, a connection pad, or other materials. The base material 101 may be a layer of, for example, copper (Cu), aluminium (Al), or an alloy of copper or aluminium. A copper alloy or an aluminium alloy may include, as an alloy component, nickel, chromium, manganese, iron, cobalt, tungsten, titanium, and/or silicon, in addition to copper or aluminium. The content of the alloy component is preferably 50% or less, and more preferably 10% or less. The thickness of the base material 101 is not specifically limited, and is preferably 0.05 μm or more, more preferably 0.1 μm or more, preferably 100 μm or less, and more preferably 60 μm or less.

The base material layer 121 can be a layer of nickel(Ni) or a nickel alloy including for example, phosphorus or boron as an alloy component. The content of the alloy component in the base material layer 121 is preferably 50% or less, and more preferably 15% or less. In particular, a nickel-phosphorus layer including phosphorus is preferable because of easiness in forming a good film. The thickness of the base material layer 121 is not specifically limited, and from the viewpoint of connection reliability, is preferably 0.05 μm or more, more preferably 0.1 μm or more, preferably 15 μm or less, and more preferably 7 μm or less.

The catalyst 122 can be one or more metals selected from the group consisting of gold (Au), palladium (Pd), platinum (Pt), silver (Ag), rhodium (Rh), cobalt (Co), tin (Sn), copper (Cu), iridium (Ir), osmium (Os), and ruthenium (Ru). Among these metals, gold, palladium, platinum, silver, and rhodium are preferable because of high catalyst effects and easiness in application. As illustrated in FIG. 1, the catalyst 122 can be formed in a layer pattern covering the entire surface of the base material layer 121. Alternatively, the catalyst 122 does not need to cover the entire surface of the base material layer 121, and may be applied in an island shape or a net shape in which part of the surface of the base material layer 121 is exposed. The thickness of a portion coated with the catalyst is not specifically limited, and from the viewpoint of forming a good surface layer 123, is preferably 0.0001 μm or more, more preferably 0.001 μm or more, and preferably 0.1 μm or less.

The surface layer 123 can be a layer of tin(Sn) or a tin alloy. From the viewpoint of connection reliability, the thickness of the surface layer 123 is 0.5 μm or more, and preferably 1.0 μm or more. The upper limit of the thickness is preferably 15 μm or less, and more preferably 10 μm or less, from the viewpoint of, for example, a film formation time. The tin alloy can include, for example, silver (Ag), copper (Cu), bismuth (Bi), or nickel (Ni), other than tin, as an alloy component. Specific examples of the tin alloy include Sn—Ag, Sn—Ag—Cu, Sn—Cu, Sn—Bi, Sn—Cu—Ni, and Sn—Cu—Bi.

The stacked films 102 according to this embodiment are formed in the following manner. After the surface of the base material 101 is subjected to treatments such as degreasing, soft etching, and pickling, the base material layer 121 is formed by using electroless nickel plating or electroless nickel alloy plating (hereinafter collectively referred to as electroless nickel platings). In a case where the base material 101 is made of, for example, copper, it is sufficient to apply a catalyst before the electroless nickel platings are performed. The catalyst can be, for example, palladium (Pd), silver (Ag), gold (Au) or platinum (Pt). In the case where the base material 101 is made of, for example, aluminium, the electroless nickel platings can be performed after a zincate process.

Then, the catalyst 122 is applied to the surface of the base material layer 121. The catalyst 122 can be applied by immersing the base material in a solution containing a salt of a potentially noble metal, for example. The catalyst application can be performed by physically adsorbing a colloidal catalytic metal onto the surface of the base material layer 121.

The surface layer 123 is formed by using an electroless tin plating bath on the base material layer 121 to which the catalyst 122 is applied. The electroless tin plating bath includes a tin compound, trivalent titanium as a reducing agent, and pyrophosphate salt as a complexing agent.

The tin compound may be any compound that produces divalent tin ions in the plating bath. Examples of the tin compound include tin(II) chloride, tin(II) sulfate, tin(II) pyrophosphate, tin(II) bromide, tin iodide(II), tin(II) fluoride, and tin(II) phosphate. Although the concentration of the tin compound in the plating bath is not specifically limited, and from the viewpoints of, for example, film quality and a precipitation rate, the tin concentration is preferably 0.1 g/L or more, more preferably 1 g/L or more, preferably 30 g/L or less, and more preferably 15 g/L or less.

Trivalent titanium as a reducing agent can be, for example, trivalent halogenated titanium or titanium sulfate, and can be titanium(III) chloride, titanium(III) bromide, titanium(III) iodide, or titanium(III) sulfate, and especially preferably titanium(III) chloride. From the viewpoints of sufficient precipitation of tin and stability of the plating bath, the concentration of trivalent titanium as a reducing agent in the plating bath is preferably 0.1 g/L or more, more preferably 1 g/L or more, preferably 10 g/L or less, and more preferably 7 g/L or less.

Pyrophosphate salt as a complexing agent can be, for example, tetrapotassium pyrophosphate, tetrasodium pyrophosphate, or sodium dihydrogen pyrophosphate. From the viewpoint of stability in the plating bath, the concentration of pyrophosphoric acid as a complexing agent in the plating bath is preferably 20 g/L or more, more preferably 50 g/L or more, preferably 400 g/L or less, and more preferably 300 g/L or less.

The use of trivalent titanium as a reducing agent and the use of pyrophosphate salt as a complexing agent can reduce generation of bath decomposition in the plating bath. Accordingly, the thick surface layer 123 can be formed so that connection reliability of the stacked films 102 can be significantly increased. In the case of a plating bath having poor bath stability, a thick tin plating layer can be formed at a laboratory level, but is difficult to be formed by industrial production. On the other hand, the plating bath according to the present disclosure is highly stable, and thus, a thick tin plating layer with a thickness of 0.5 μm or more can be easily formed by industrial production.

The electroless tin plating bath according to this embodiment may include nitrogen-free organic thiol as an accelerating agent for accelerating precipitation of tin. Examples of the nitrogen-free organic thiol include 1-propanethiol, 1-botanethiol, 1,2-ethanedithiol, 1,2-propanedithiol, 1,4-butanedithiol, 1,5-pentanedithiol, 1,6-hexanedithiol, 2-aminoethanethiol, 3-mercapto-1,2-propanediol, 1,4-dimercapto-2,3-butanediol, 3-ethyl mercaptopropionate, benzenethiol, benzenetrithiol, 2,3-dichlorobenzenethiol, 2,4-dimethylbenzenethiol, 2-aminobenzenethiol, 2-naphtalenethiol, mercaptobenzoic acid, mercaptosuccinic acid, 3-mercaptopropionic acid, mercaptoacetic acid, mercaptosalicylic acid, 2-mercaptopropionic acid, 6-mercaptol-hexanol, 3-mercaptopropanol, 3-mercapto-1-hexanol, 3-mercaptoethanol, 2-sodium mercaptoethanesulfonate, 3-mercapto-1-sodium propanesulfonate, and 2,3-sodium dimercaptopropanesulfonate monohydrate. Nitrogen-free organic thiol can accelerate plating precipitation. The concentration of nitrogen-free organic thiol is preferably 0.1 g/L or more, more preferably 0.2 g/L or more, preferably 10 g/L or less, and more preferably 5 g/L or less.

From the viewpoint of accelerating plating precipitation to reduce a cycle time, the plating bath preferably includes an accelerating agent, but when trivalent titanium is used as a reducing agent and pyrophosphate salt is used as a complexing agent, a thick tin plating layer can be formed with stability even in the case of including no accelerating agent such as nitrogen-free organic thiol.

The electroless tin plating bath according to this embodiment can use, as an accelerating agent, sulfur oxoacid instead of nitrogen-free organic thiol or together with nitrogen-free organic thiol. Examples of sulfur oxoacid include dithionic acid, trithionic acid, tetrathionic acid, dithionous acid, and thiosulfuric acid. These materials may be in the state of salts. Examples of the salt include a sodium salt, a potassium salt, and an ammonium salt Specifically, the salt may be sodium tetrathionate, potassium tetrathionate, sodium trithionate, sodium dithionate, sodium dithionite, sodium thiosulfate, potassium thiosulfate, and ammonium thiosulfate. Sulfur oxoacid can accelerate plating precipitation. The concentration of sulfur oxoacid is preferably 0.1 mg/L or more, more preferably 1 mg/L or more, preferably 10 g/L or less, and more preferably 1 g/L or less.

The electroless tin plating solution according to this embodiment may include an antioxidant. The antioxidant may be, for example, one or more of catechol, pyrogallol, resorcinol, hydrochinone, ascorbic acid, and sorbitol. From the viewpoint of stability of the plating bath, the concentration of the antioxidant is preferably 0.1 g/L or more, preferably 50 g/L or less, and more preferably 10 g/L or less.

The pH of the electroless tin plating bath according to this embodiment is preferably 5.0 or more, more preferably 7.0 or more, preferably 10.0 or less, and more preferably 9.0 or less. To adjust the pH within an appropriate range, a pH adjuster can be used. Examples of the pH adjuster include inorganic acids such as phosphoric acid, hydrochloric acid, sulfuric acid, and nitric acid and organic acids such as formic acid, acetic acid, malic acid, and lactic acid. A compound having a buffer function such as a phosphoric acid buffer can also be used. Alternatively, a surfactant and a brightener may also be included, for example.

The bath temperature of the electroless tin plating bath in precipitating the surface layer 123 is preferably 40° C. or more, more preferably 60° C. or more, preferably 90° C. or less, and more preferably 80° C. or less. The plating time is preferably 10 minutes or more, preferably 180 minutes or less, and more preferably 60 minutes or less.

The electroless tin plating bath according to this embodiment can use titanium that has been oxidized from trivalent to tetravalent with the progress of plating and then reduced to trivalent again by an electroreduction process, for example. The reduction of tetravalent titanium to trivalent titanium can be performed by using, for example, an electroreduction tank 201 as illustrated in FIG. 2. The electroreduction tank 201 is divided into an anode chamber 211 and a cathode chamber 212 by a cation exchange membrane 213. An anode 215 of, for example, a titanium-platinum alloy is disposed in the anode chamber 211, and a cathode 216 of, for example, metal tin is disposed in the cathode chamber 212. An anode solution such as sulfuric acid is supplied to the anode chamber 211 and a plating solution is supplied to the cathode chamber 212 and a current is caused to flow so that tetravalent titanium is reduced to trivalent titanium on the cathode 216. As side reaction, tin ions are reduced to a metal and H+s reduced so that a hydrogen gas is generated.

The reduction from tetravalent titanium to trivalent titanium can be performed by a batch process, and may be performed in parallel with a plating process. In this case, it is sufficient that the plating solution circulates between the plating tank where the plating process is performed and the cathode chamber 212 of the electroreduction tank 201. In this case, a method in which a constant amount of the plating solution in the plating tank is fed to the electroreduction tank and is sent back to the plating tank after the electroreduction process, or a continuous circulation method in which the plating solution continuously circulates between the plating tank and the electroreduction tank, may be employed.

In the method for fabricating an electronic component according to this embodiment, a tin plating film with a thickness of 0.5 μm or more can be formed with stability on, for example, a printed wiring board and a wafer. Thus, even in a case where a thermal hysteresis is large in assembly, it is possible to avoid a situation where a tin plating film is alloyed with an underlying material and disappears, and connection reliability can be thereby significantly enhanced. As a result, the method according to this embodiment is useful as a method for fabricating an electronic component that requires connection reliability, for example.

### EXAMPLES

The present disclosure will now be more specifically described with reference to examples. The following examples are illustrative examples and are not intended to limit the present disclosure.

### <Connection Reliability Test>

Stacked films including a base material layer, a catalytic metal, and a surface layer were formed by a predetermined plating bath on a ball grid array (BGA) substrate (manufactured by C. Uyemura & Co., Ltd.). Solder balls (Sn-3.0 Ag-0.5 Cu-based solder balls with (φ) of 0.6 mm, manufactured by SENJU METAL INDUSTRY CO., LTD.) were joined to the BGA substrate with the stacked films, by using fluxes (529D-1, manufactured by SENJU METAL INDUSTRY CO., LTD.). The joint of solder balls was performed such that after the BGA substrate was subjected to a reflow process at a maximum temperature of 240° C., solder balls were mounted, and then, a reflow process was performed again at a maximum temperature of 240° C.

A ball pull test was conducted on the solder balls after the reflow process to obtain a solder fracture rate in a destructive mode. A result in which the solder fracture rate was 80% or more was evaluated as good (connected), and a result in which the solder fracture rate is less than 80% was evaluated as poor (disconnected).

### <Electroless Tin Plating Bath>

As a plating bath A, a plating bath including tin(II) chloride in a tin concentration of 10 g/L as a tin compound, 5 g/L of titanium(III) chloride as a reducing agent, 200 g/L of potassium pyrophosphate as a complexing agent, 2 g/L of thiomalic acid as nitrogen-free organic thiol was prepared.

As a plating bath B, a plating bath including tin(II) chloride in a tin concentration of 10 g/L as a tin compound, 5 g/L of titanium(III) chloride as a reducing agent, 50 g/L of ethylenediaminetetraacetic acid (EDTA) as a complexing agent, and 2 g/L of thiomalic acid as nitrogen-free organic thiol was prepared.

As a plating bath C, a plating bath including tin(II) chloride in a tin concentration of 10 g/L as a tin compound, 0.5 g/L of sodium borohydride as a reducing agent, 200 g/L of potassium pyrophosphate as a complexing agent, and 2 g/L of thiomalic acid as nitrogen-free organic thiol was prepared.

As a plating bath D, a plating bath including tin(II) chloride in a tin concentration of 10 g/L as a tin compound, 0.5 g/L of sodium borohydride as a reducing agent, 50 g/L of ethylenediaminetetraacetic acid (EDTA) as a complexing agent, and 2 g/L of thiomalic acid as nitrogen-free organic thiol was prepared.

As a plating bath E, a plating path including tin(II) chloride in a tin concentration of 10 g/L as a tin compound, 5 g/L of titanium(III) chloride as a reducing agent, 200 g/L of potassium pyrophosphate as a complexing agent, and 100 mg/L of sodium thiosulfate as sulfur oxoacid was prepared.

As a plating bath F, a plating bath including tin(II) chloride in a tin concentration of 10 g/L as a tin compound, 5 g/L of titanium(III) chloride as a reducing agent, 200 g/L of potassium pyrophosphate as a complexing agent, and 1 g/L of sodium dithionite as sulfur oxoacid was prepared.

As a plating bath G, a plating bath including tin(II) chloride in a tin concentration of 10 g/L as a tin compound, 5 g/L of titanium(III) chloride as a reducing agent, 200 g/L of potassium pyrophosphate as a complexing agent, and 1 g/L of potassium tetrathionate as sulfur oxoacid was prepared.

As a plating bath H, a plating path including tin(II) chloride in a tin concentration of 10 g/L as a tin compound, 5 g/L of titanium(III) chloride as a reducing agent, 50 g/L of ethylenediaminetetraacetic acid (EDTA) as a complexing agent, and 100 mg/L of sodium thiosulfate as sulfur oxoacid was prepared.

As a plating bath I, a plating path including tin(II) chloride in a tin concentration of 10 g/L as a tin compound, 0.5 g/L of sodium borohydride as a reducing agent, 200 g/L of potassium pyrophosphate as a complexing agent, and 100 mg/L of sodium thiosulfate as sulfur oxoacid was prepared.

As a plating bath J, a plating path including tin(II) chloride in a tin concentration of 10 g/L as a tin compound, 0.5 g/L of sodium borohydride as a reducing agent, 50 g/L of ethylenediaminetetraacetic acid (EDTA) as a complexing agent, and 100 mg/L of sodium thiosulfate as sulfur oxoacid was prepared.

Tables 1 and 2 collectively show compositions of prepared electroless tin plating baths.

TABLE 1

| | Electroless Sn Plating Bath | | | |
|---|---|---|---|---|
| | Plating Bath | Plating Bath | Plating Bath | Plating Bath |
| | A | B | C | D |
| Reducing | trivalent | trivalent | sodium | sodium |
| Agent | titanium | titanium | borahydride | borohydride |
| | 5.0 (g/L) | 5.0 (g/L) | 0.5 (g/L) | 0.5 (g/L) |
| Complexing | pyrophosphate | EDTA | pyrophosphate | EDTA |
| Agent | salt | 50 (g/L) | salt | 50 (g/L) |
| | 200 (g/L) | | 200 (g/L) | |
| tin(II) | 10 (g/L) | 10 (g/L) | 10 (g/L) | 10 (g/L) |
| chloride (Sn | | | | |
| compound) | | | | |
| thiomalic | 2 (g/L) | 2 (g/L) | 2 (g/L) | 2 (g/L) |
| acid | | | | |
| (nitrogen- | | | | |
| free organic | | | | |
| thiol) | | | | |

TABLE 2

| | Electroless Sn Plating Bath | | | | | |
|---|---|---|---|---|---|---|
| | Plating | Plating | Plating | Plating | Plating | Plating |
| | Bath E | Bath F | Bath G | Bath H | Bath I | Bath J |
| Reducing | trivalent | trivalent | trivalent | trivalent | sodium | sodium |
| Agent | titanium | titanium | titanium | titanium | borohydride | borohydride |
| | 5.0 (g/L) | 5.0 (g/L) | 5.0 (g/L) | 5.0 (g/L) | 0.5 (g/L) | 0.5 (g/L) |
| Complexing | pyrophos- | pyrophos- | pyrophos- | EDTA | pyrophos- | EDTA |
| Agent | phate salt | phate salt | phate salt | 50 (g/L) | phate salt | 50 (g/L) |
| | 200 (g/L) | 200 (g/L) | 200 (g/L) | | 200 (g/L) | |
| tin(II) | 10 (g/L) | 10 (g/L) | 10 (g/L) | 10 (g/L) | 10 (g/L) | 10 (g/L) |
| chloride (Sn | | | | | | |
| compound) | | | | | | |
| sulfur | sodium | dithionous | potassium | sodium | sodium | sodium |
| oxoacid | thiosulfate | acid | tetrathio- | thiosulfate | thiosulfate | thiosulfate |
| | 100 (mg/L) | 1 (g/L) | nate | 100 (mg/L) | 100 (mg/L) | 100 (mg/L) |
| | | | 1 (g/L) | | | |

### <Bath Stability>

When a prepared electroless tin plating bath is left for one hour at a plating temperature of 70° C., it is determined whether precipitation (beaker precipitation) occurs or not A result in which precipitation does not occur is represented as “good” and a result in which precipitation occurs is represented as “poor.”

### Example 1

As a pretreatment, degreasing, softetching, and pickling were performed on the surface of a copper underlying layer (base material layer). A palladium catalyst was applied onto the underlying layer subjected to the pretreatment, and a base material layer with a thickness of 2.0 μm was formed by an electroless nickel plating bath (electroless Ni plating solution NPR-4, manufactured by C. Uyemura & Co., Ltd.). After silver (Ag) was applied as a catalytic metal to the base material layer, a surface layer with a thickness of 0.5 μm was formed by using the electroless plating bath A. The plating time was 15 minutes, and the plating temperature was 70° C. The thickness was measured by a fluorescent X-ray coating thickness gauge (FT150, manufactured by Hitachi High-Tech Science Corporation).

In a case where the plating bath was allowed to stand for one hour at a plating temperature of 70° C., bath decomposition did not cause beaker precipitation, and the plating bath was stable. Under the same conditions, a film was formed on a BGA substrate and a connection reliability test was conducted. The result of the test was good.

### Example 2

Example 2 is similar to Example 1 except that the catalytic metal was palladium (Pd). The connection reliability test was good.

### Example 3

Example 3 is similar to Example 1 except that the catalytic metal was gold (Au). The connection reliability test was good.

### Example 4

As a pretreatment, degreasing, pickling, primary zincate, pickling, and secondary zincate were performed on the surface of an underlying layer of an aluminium-copper alloy. A palladium catalyst was applied to the pretreated underlying layer, and a base material layer with a thickness of 2.0 μm was formed by using an electroless nickel plating bath (electroless Ni plating solution NPR-4, manufactured by C. Uyemura & Co., Ltd.). Silver (Ag) was applied as a catalytic metal to the base material layer, and a surface layer having a 0.5 μm was formed by using the electroless plating bath A. The plating time was 15 minutes, and the plating temperature was 70° C.

Under the same conditions, a film was formed on a BGA substrate, and a connection reliability test was conducted. The result of the test was good.

### Example 5

Example 5 is similar to Example 4 except that the catalytic metal was palladium (Pd). The result of the connection reliability test was good.

### Example 6

Example 6 is similar to Example 4 except that the catalytic metal was gold (Au). The result of the connection reliability test was good.

### Comparative Example 1

Comparative Example 1 is similar to Example 1 except that no catalytic metal was applied to the base material layer. Tin precipitation did not occur, and no surface layer was formed. A connection reliability test was conducted without formation of a surface layer. The result of the test was poor.

### Comparative Example 2

Comparative Example 2 is similar to Example 4 except that no catalytic metal was applied to the base material layer. Tin precipitation did not occur, and no surface layer was formed. A connection reliability test was conducted without formation of a surface layer. The result of the test was poor.

### Comparative Example 3

Comparative Example 3 is similar to Example 1 except that the plating time was 12 minutes, the plating temperature was 70° C., and the thickness of the surface layer was 0.4 μm. The result of the connection reliability test was poor.

### Comparative Example 4

Comparative Example 4 is similar to Example 2 except that the plating time was 12 minutes, the plating temperature was 70° C., and the thickness of the surface layer was 0.4 μm. The result of the connection reliability test was poor.

### Comparative Example 5

Comparative Example 5 is similar to Example 3 except that the plating time was 12 minutes, the plating temperature was 70° C., and the thickness of the surface layer was 0.4 μm. The result of the connection reliability test was poor.

### Comparative Example 6

Comparative Example 6 is similar to Example 4 except that the plating time was 12 minutes, the plating temperature was 70° C., and the thickness of the surface layer was 0.4 μm. The result of the connection reliability test was poor.

### Comparative Example 7

Comparative Example 7 is similar to Example 5 except that the plating time was 12 minutes, the plating temperature was 70° C., and the thickness of the surface layer was 0.4 μm. The result of the connection reliability test was poor.

### Comparative Example 8

Comparative Example 8 is similar to Example 6 except that the plating time was 12 minutes, the plating temperature was 70° C., and the thickness of the surface layer was 0.4 μm. The result of the connection reliability test was poor.

### Comparative Example 9

Comparative Example 9 is similar to Example 1 except that the electroless tin plating bath B was used, the plating time was 5 minutes, the plating temperature was 70° C., and the thickness of the surface layer was 0.1 μm. After the plating bath was left in one hour at the plating temperature, beaker precipitation occurred and the plating bath was unstable. The result of the connection reliability test was poor.

### Comparative Example 10

Comparative Example 10 is similar to Example 2 except that the electroless tin plating bath B was used, the plating time was 5 minutes, the plating temperature was 70° C., and the thickness of the surface layer was 0.1 μm. The result of the connection reliability test was poor.

### Comparative Example 11

Comparative Example 11 is similar to Example 3 except that the electroless tin plating bath B was used, the plating time was 5 minutes, the plating temperature was 70° C., and the thickness of the surface layer was 0.1 μm. The result of the connection reliability test was poor.

### Comparative Example 12

Comparative Example 12 is similar to Example 4 except that the electroless tin plating bath B was used, the plating time was 5 minutes, the plating temperature was 70° C., and the thickness of the surface layer was 0.1 μm. The result of the connection reliability test was poor.

### Comparative Example 13

Comparative Example 13 is similar to Example 5 except that the electroless tin plating bath B was used, the plating time was 5 minutes, the plating temperature was 70° C., and the thickness of the surface layer was 0.1 μm. The result of the connection reliability test was poor.

### Comparative Example 14

Comparative Example 13 is similar to Example 6 except that the electroless tin plating bath B was used, the plating time was 6 minutes, the plating temperature was 70° C., and the thickness of the surface layer was 0.1 μm. The result of the connection reliability test was poor.

### Comparative Example 15

Comparative Example 15 is similar to Example 9 except that the plating time was 25 minutes, the plating temperature was 70° C., and the thickness of the surface layer was 0.5 μm. The result of the connection reliability test was good, but repetitive use was difficult because of unstable plating bath.

### Comparative Example 16

Comparative Example 16 is similar to Example 1 except that the electroless tin plating bath C was used, the plating time was 5 minutes, the plating temperature was 70° C., and the thickness of the surface layer was 0.1 μm. After the plating bath was left in one hour at the plating temperature, beaker precipitation occurred and the plating bath was unstable. The result of the connection reliability test was poor.

### Comparative Example 17

Comparative Example 17 is similar to Example 2 except that the electroless tin plating bath C was used, the plating time was 5 minutes, the plating temperature was 70° C., and the thickness of the surface layer was 0.1 μm. The result of the connection reliability test was poor.

### Comparative Example 18

Comparative Example 18 is similar to Example 3 except that the electroless tin plating bath C was used, the plating time was 5 minutes, the plating temperature was 70° C., and the thickness of the surface layer was 0.1 μm. The result of the connection reliability test was poor.

### Comparative Example 19

Comparative Example 19 is similar to Example 4 except that the electroless tin plating bath C was used, the plating time was 5 minutes, the plating temperature was 70° C., and the thickness of the surface layer was 0.1 μm. The result of the connection reliability test was poor.

### Comparative Example 20

Comparative Example 20 is similar to Example 5 except that the electroless tin plating bath C was used, the plating time was 5 minutes, the plating temperature was 70° C., and the thickness of the surface layer was 0.1 μm. The result of the connection reliability test was poor.

### Comparative Example 21

Comparative Example 21 is similar to Example 6 except that the electroless tin plating bath C was used, the plating time was 5 minutes, the plating temperature was 70° C., and the thickness of the surface layer was 0.1 μm. The result of the connection reliability test was poor.

### Comparative Example 22

Comparative Example 22 is similar to Example 17 except that the plating time was 25 minutes, the plating temperature was 70° C., and the thickness of the surface layer was 0.5 μm. The result of the connection reliability test was good, but repetitive use was difficult because of unstable plating bath.

### Comparative Example 23

Comparative Example 23 is similar to Example 1 except that the electroless tin plating bath D was used, the plating time was 5 minutes, the plating temperature was 70° C., and the thickness of the surface layer was 0.1 μm. After the plating bath was left in one hour at the plating temperature, beaker precipitation occurred and the plating bath was unstable. The result of the connection reliability test was poor.

### Comparative Example 24

Comparative Example 24 is similar to Example 2 except that the electroless tin plating bath D was used, the plating time was 5 minutes, the plating temperature was 70° C., and the thickness of the surface layer was 0.1 μm. The result of the connection reliability test was poor.

### Comparative Example 25

Comparative Example 25 is similar to Example 3 except that the electroless tin plating bath D was used, the plating time was 5 minutes, the plating temperature was 70° C., and the thickness of the surface layer was 0.1 μm. The result of the connection reliability test was poor.

### Comparative Example 26

Comparative Example 26 is similar to Example 4 except that the electroless tin plating bath D was used, the plating time was 5 minutes, the plating temperature was 70° C., and the thickness of the surface layer was 0.1 μm. The result of the connection reliability test was poor.

### Comparative Example 27

Comparative Example 27 is similar to Example 5 except that the electroless tin plating bath D was used, the plating time was 5 minutes, the plating temperature was 70° C., and the thickness of the surface layer was 0.1 μm. The result of the connection reliability test was poor.

### Comparative Example 28

Comparative Example 28 is similar to Example 6 except that the electroless tin plating bath D was used, the plating time was 5 minutes, the plating temperature was 70° C., and the thickness of the surface layer was 0.1 μm. The result of the connection reliability test was poor.

### Comparative Example 29

Comparative Example 29 is similar to Example 25 except that the plating time was 25 minutes, the plating temperature was 70° C., and the thickness of the surface layer was 0.5 μm. The result of the connection reliability test was good, but repetitive use was difficult because of unstable plating bath.

Tables 3 through 7 collectively show results of the examples and the comparative examples.

TABLE 3

| | Examples | | | | | |
|---|---|---|---|---|---|---|
| | 1 | 2 | 3 | 4 | 5 | 6 |
| Base Material | Cu | Qu | Cu | Al—Cu | Al—Cu | Al—Cu |
| Layer | | | | | | |
| Catalytic | Ag | Pd | Au | Ag | Pd | Au |
| Metal | | | | | | |
| Sn Plating | A | A | A | A | A | A |
| Bath | | | | | | |
| Surface Layer | 0.5 | 0.5 | 0.5 | 0.5 | 0.5 | 0.5 |
| Thickness | | | | | | |
| (μm) | | | | | | |
| Stability | good | good | good | good | good | good |
| Connection | good | good | good | good | good | good |
| Reliability | | | | | | |

TABLE 4

| | Comparative Examples | | | | | | | |
|---|---|---|---|---|---|---|---|---|
| | 1 | 2 | 3 | 4 | 5 | 6 | 7 | 8 |
| Bass Material | Cu | Al—Cu | Cu | Cu | C | Al—Cu | Al—Cu | Al—Cu |
| Layer | | | | | | | | |
| Catalytic Metal | — | — | Ag | Pd | Au | Ag | Pd | Au |
| Sn Plating Bath | A | A | A | A | A | A | A | A |
| Surface Layer | unprecipitated | unprecipitated | 04 | 0.4 | 0.4 | 0.4 | 0.4 | 0.4 |
| Thickness (μm) | | | | | | | | |
| Stability | good | good | good | good | good | good | good | good |
| Connection | poor | poor | poor | poor | poor | poor | poor | poor |
| Reliability | | | | | | | | |

TABLE 5

| | Comparative Examples | | | | | | |
|---|---|---|---|---|---|---|---|
| | 8 | 10 | 11 | 12 | 13 | 14 | 15 |
| Bass Material | Cu | Cu | Ou | Al—Cu | Al—Cu | Al—Cu | Cu |
| Layer | | | | | | | |
| Catalytic | Ag | Pd | Au | As | Pd | Au | Ag |
| Metal | | | | | | | |
| Sn Plating | B | B | B | B | B | B | B |
| Bath | | | | | | | |
| Surface Layer | 0.1 | 0.1 | 0.1 | 0.1 | 01 | 0.1 | 0.5 |
| Thickness | | | | | | | |
| (μm) | | | | | | | |
| Stability | poor | poor | poor | poor | poor | poor | poor |
| Connection | poor | poor | poor | poor | poor | poor | good |
| Reliability | | | | | | | |

TABLE 6

| | Comparative Examples | | | | | | |
|---|---|---|---|---|---|---|---|
| | 16 | 17 | 18 | 19 | 20 | 21 | 22 |
| Base Material | Cu | Cu | Cu | Al—Cu | Al—Cu | Al—Cu | Cu |
| Layer | | | | | | | |
| Catalytic | Ag | Pd | Au | Ag | Pd | Au | Pd |
| Metal | | | | | | | |
| Sn Plating | C | C | C | C | C | C | C |
| Bath | | | | | | | |
| Surface Layer | 0.1 | 0.1 | 0.1 | 0.1 | 0.1 | 0.1 | 0.5 |
| Thickness | | | | | | | |
| (μm) | | | | | | | |
| Stability | poor | poor | poor | poor | poor | poor | poor |
| Connection | poor | poor | poor | poor | poor | poor | good |
| Reliability | | | | | | | |

TABLE 7

| | Comparative Examples | | | | | | |
|---|---|---|---|---|---|---|---|
| | 23 | 24 | 25 | 26 | 27 | 28 | 29 |
| Base Material | Cu | Cu | Cu | Al—Cu | Al—Cu | Al—Cu | Cu |
| Laver | | | | | | | |
| Catalytic | Ag | Pd | Au | Ag | Pd | Au | Au |
| Metal | | | | | | | |
| Sn Plating | D | D | D | D | D | D | D |
| Bath | | | | | | | |
| Surface Layer | 0.1 | 0.1 | 0.1 | 0.1 | 0.1 | 0.1 | 0.5 |
| Thickness | | | | | | | |
| (μm) | | | | | | | |
| Stability | poor | poor | poor | poor | poor | poor | poor |
| Connection | poor | poor | poor | poor | poor | poor | good |
| Reliability | | | | | | | |

### Example 7

In a manner similar to Example 1, the base material layer was made of Cu, the catalytic metal applied to the base material layer was Ag, and plating was performed for 15 minutes at 70° C. by using the electroless tin plating bath E so that a surface layer with a thickness of 0.5 μm was formed. In a case where the plating bath was allowed to stand for one hour at a plating temperature of 70° C., bath decomposition did not cause beaker precipitation, and the plating bath was stable. The result of the connection reliability test was good.

### Example 8

Example 8 is similar to Example 7 except that the catalytic metal was palladium (Pd). The result of the connection reliability test was good.

### Example 9

Example 9 is similar to Example 7 except that the catalytic metal was gold (Au). The result of the connection reliability test was good.

### Example 10

In a manner similar to Example 4, the base material layer was made of Al—Cu, the catalytic metal applied to the base material layer was Ag, and plating was performed for 15 minutes at 70° C. by using the electroless tin plating bath E so that a surface layer with a thickness of 0.5 μm was formed. The result of the connection reliability test was good.

### Example 11

Example 11 is similar to Example 10 except that the catalytic metal was palladium (Pd). The result of the connection reliability test was good.

### Example 12

Example 12 is similar to Example 10 except that the catalytic metal was gold (Au). The result of the connection reliability test was good.

### Example 13

Example 13 is similar to Example 7 except that the electroless tin plating bath F was used. In a case where the plating bath was allowed to stand for one hour at a plating temperature of 70° C., bath decomposition did not cause beaker precipitation, and the plating bath was stable. The result of the connection reliability test was good.

### Example 14

Example 14 is similar to Example 13 except that the catalytic metal was palladium (Pd). The result of the connection reliability test was good.

### Example 15

Example 15 is similar to Example 13 except that the catalytic metal was gold (Au). The result of the connection reliability test was good.

### Example 16

Example 16 is similar to Example 10 except that the electroless tin plating bath F was used. The result of the connection reliability test was good.

### Example 17

Example 17 is similar to Example 16 except that the catalytic metal was palladium (Pd). The result of the connection reliability test was good.

### Example 18

Example 18 is similar to Example 16 except that the catalytic metal was gold (Au). The result of the connection reliability test was good.

### Example 19

Example 19 is similar to Example 7 except that the electroless tin plating bath G was used. In a case where the plating bath was allowed to stand for one hour at a plating temperature of 70° C., bath decomposition did not cause beaker precipitation, and the plating bath was stable. The result of the connection reliability test was good.

### Example 20

Example 20 is similar to Example 19 except that the catalytic metal was palladium (Pd). The result of the connection reliability test was good.

### Example 21

Example 21 is similar to Example 19 except that the catalytic metal was gold (Au). The result of the connection reliability test was good.

### Example 22

Example 22 is similar to Example 10 except that the electroless tin plating bath G was used. The result of the connection reliability test was good.

### Example 23

Example 23 is similar to Example 22 except that the catalytic metal was palladium (Pd). The result of the connection reliability test was good.

### Example 24

Example 24 is similar to Example 22 except that the catalytic metal was gold (Au). The result of the connection reliability test was good.

### Comparative Example 30

Comparative Example 30 is similar to Example 7 except that no catalytic metal was applied to the surface layer. Tin precipitation did not occur, and no surface layer was formed. A connection reliability test was conducted without formation of a surface layer. The result of the test was poor.

### Comparative Example 31

Comparative Example 31 is similar to Example 10 except that no catalytic metal was applied to the surface layer. Tin precipitation did not occur, and no surface layer was formed. A connection reliability test was conducted without formation of a surface layer. The result of the test was poor.

### Comparative Example 32

Comparative Example 32 is similar to Example 7 except that the plating time was 12 minutes, the plating temperature was 70° C., and the thickness of the surface layer was 0.4 μm. The result of the connection reliability test was poor.

### Comparative Example 33

Comparative Example 33 is similar to Example 8 except that the plating time was 12 minutes, the plating temperature was 70° C., and the thickness of the surface layer was 0.4 μm. The result of the connection reliability test was poor.

### Comparative Example 34

Comparative Example 34 is similar to Example 9 except that the plating time was 12 minutes, the plating temperature was 70° C., and the thickness of the surface layer was 0.4 μm. The result of the connection reliability test was poor.

### Comparative Example 35

Comparative Example 35 is similar to Example 10 except that the plating time was 12 minutes, the plating temperature was 70° C., and the thickness of the surface layer was 0.4 μm. The result of the connection reliability test was poor.

### Comparative Example 36

Comparative Example 36 is similar to Example 11 except that the plating time was 12 minutes, the plating temperature was 70° C., and the thickness of the surface layer was 0.4 μm. The result of the connection reliability test was poor.

### Comparative Example 37

Comparative Example 37 is similar to Example 12 except that the plating time was 12 minutes, the plating temperature was 70° C., and the thickness of the surface layer was 0.4 μm. The result of the connection reliability test was poor.

### Comparative Example 38

Comparative Example 38 is similar to Example 7 except that the electroless tin plating bath H was used, the plating time was 5 minutes, the plating temperature was 70° C., and the thickness of the surface layer was 0.1 μm. After the plating bath was left in one hour at a plating temperature of 70° C., beaker precipitation occurred and the plating bath was unstable. The result of the connection reliability test was poor.

### Comparative Example 39

Comparative Example 39 is similar to Example 8 except that the electroless tin plating bath H was used, the plating time was 5 minutes, the plating temperature was 70° C., and the thickness of the surface layer was 0.1 μm. The result of the connection reliability test was poor.

### Comparative Example 40

Comparative Example 40 is similar to Example 9 except that the electroless tin plating bath H was used, the plating time was 5 minutes, the plating temperature was 70° C., and the thickness of the surface layer was 0.1 μm. The result of the connection reliability test was poor.

### Comparative Example 41

Comparative Example 41 is similar to Example 10 except that the electroless tin plating bath H was used, the plating time was 5 minutes, the plating temperature was 70° C., and the thickness of the surface layer was 0.1 μm. The result of the connection reliability test was poor.

### Comparative Example 42

Comparative Example 42 is similar to Example 11 except that the electroless tin plating bath H was used, the plating time was 5 minutes, the plating temperature was 70° C., and the thickness of the surface layer was 0.1 μm. The result of the connection reliability test was poor.

### Comparative Example 43

Comparative Example 43 is similar to Example 12 except that the electroless tin plating bath H was used, the plating time was 5 minutes, the plating temperature was 70° C., and the thickness of the surface layer was 0.1 μm. The result of the connection reliability test was poor.

### Comparative Example 44

Comparative Example 44 is similar to Example 38 except that the plating time was 25 minutes, the plating temperature was 70° C., and the thickness of the surface layer was 0.5 μm. The result of the connection reliability test was good, but repetitive use was difficult because of unstable plating bath.

### Comparative Example 45

Comparative Example 45 is similar to Example 7 except that the electroless tin plating bath I was used, the plating time was 5 minutes, the plating temperature was 70° C., and the thickness of the surface layer was 0.1 μm. After the plating bath was left in one hour at a plating temperature of 70° C., beaker precipitation occurred and the plating bath was unstable. The result of the connection reliability test was poor.

### Comparative Example 46

Comparative Example 46 is similar to Example 8 except that the electroless tin plating bath I was used, the plating time was 5 minutes, the plating temperature was 70° C., and the thickness of the surface layer was 0.1 μm. The result of the connection reliability test was poor.

### Comparative Example 47

Comparative Example 47 is similar to Example 9 except that the electroless tin plating bath I was used, the plating time was 5 minutes, the plating temperature was 70° C., and the thickness of the surface layer was 0.1 μm. The result of the connection reliability test was poor.

### Comparative Example 48

Comparative Example 48 is similar to Example 10 except that the electroless tin plating bath I was used, the plating time was 5 minutes, the plating temperature was 70° C., and the thickness of the surface layer was 0.1 μm. The result of the connection reliability test was poor.

### Comparative Example 49

Comparative Example 49 is similar to Example 11 except that the electroless tin plating bath I was used, the plating time was 5 minutes, the plating temperature was 70° C., and the thickness of the surface layer was 0.1 μm. The result of the connection reliability test was poor.

### Comparative Example 50

Comparative Example 50 is similar to Example 12 except that the electroless tin plating bath I was used, the plating time was 5 minutes, the plating temperature was 70° C., and the thickness of the surface layer was 0.1 μm. The result of the connection reliability test was poor.

### Comparative Example 51

Comparative Example 51 is similar to Example 46 except that the plating time was 25 minutes, the plating temperature was 70° C., and the thickness of the surface layer was 0.5 μm. The result of the connection reliability test was good, but repetitive use was difficult because of unstable plating bath.

### Comparative Example 52

Comparative Example 52 is similar to Example 7 except that the electroless tin plating bath J was used, the plating time was 5 minutes, the plating temperature was 70° C., and the thickness of the surface layer was 0.1 μm. After the plating bath was left in one hour at a plating temperature of 70° C., beaker precipitation occurred and the plating bath was unstable. The result of the connection reliability test was poor.

### Comparative Example 53

Comparative Example 53 is similar to Example 8 except that the electroless tin plating bath J was used, the plating time was 5 minutes, the plating temperature was 70° C., and the thickness of the surface layer was 0.1 μm. The result of the connection reliability test was poor.

### Comparative Example 54

Comparative Example 54 is similar to Example 9 except that the electroless tin plating bath J was used, the plating time was 5 minutes, the plating temperature was 70° C., and the thickness of the surface layer was 0.1 μm. The result of the connection reliability test was poor.

### Comparative Example 55

Comparative Example 55 is similar to Example 10 except that the electroless tin plating bath J was used, the plating time was 5 minutes, the plating temperature was 70° C., and the thickness of the surface layer was 0.1 μm. The result of the connection reliability test was poor.

### Comparative Example 56

Comparative Example 56 is similar to Example 11 except that the electroless tin plating bath J was used, the plating time was 5 minutes, the plating temperature was 70° C., and the thickness of the surface layer was 0.1 μm. The result of the connection reliability test was poor.

### Comparative Example 57

Comparative Example 57 is similar to Example 12 except that the electroless tin plating bath J was used, the plating time was 5 minutes, the plating temperature was 70° C., and the thickness of the surface layer was 0.1 μm. The result of the connection reliability test was poor.

### Comparative Example 58

Comparative Example 58 is similar to Example 54 except that the plating time was 25 minutes, the plating temperature was 70° C., and the thickness of the surface layer was 0.5 μm. The result of the connection reliability test was good, but repetitive use was difficult because of unstable plating bath.

Tables 8 through 14 collectively show results of the examples and the comparative examples.

TABLE 8

| | Examples | | | | | |
|---|---|---|---|---|---|---|
| | 7 | 8 | 9 | 10 | 11 | 12 |
| Base Material | Cu | Cu | Cu | Al—Cu | Al—Cu | Al—Cu |
| Layer | | | | | | |
| Catalytic | Ag | Pd | Au | Ag | Pd | Au |
| Metal | | | | | | |
| Sn Plating | E | E | E | E | E | E |
| Bath | | | | | | |
| Surface Layer | 0.5 | 0.5 | 0.5 | 0.5 | 0.5 | 0.5 |
| Thickness | | | | | | |
| (μm) | | | | | | |
| Stability | good | good | good | good | good | good |
| Connection | good | good | good | good | good | good |
| Reliability | | | | | | |

TABLE 9

| | Examples | | | | | |
|---|---|---|---|---|---|---|
| | 13 | 14 | 15 | 16 | 17 | 18 |
| Base Material | Cu | Cu | Cu | Al—Cu | Al—Cu | Al—Cu |
| Layer | | | | | | |
| Catalytic | Ag | Pd | Au | Ag | Pd | Au |
| Metal | | | | | | |
| Sn Plating | F | F | F | F | F | F |
| Bath | | | | | | |
| Surface Layer | 0.5 | 0.5 | 0.5 | 0.5 | 0.5 | 0.5 |
| Thickness | | | | | | |
| (μm) | | | | | | |
| Stability | good | good | good | good | good | good |
| Connection | good | good | good | good | good | good |
| Reliability | | | | | | |

TABLE 10

| | Examples | | | | | |
|---|---|---|---|---|---|---|
| | 19 | 20 | 21 | 22 | 23 | 24 |
| Base Material | Cu | Cu | Cu | Al—Cu | Al—Cu | Al—Cu |
| Layer | | | | | | |
| Catalytic | Ag | Pd | Au | Ag | Pd | Au |
| Metal | | | | | | |
| Sn Plating | G | G | G | G | G | G |
| Bath | | | | | | |
| Surface Layer | 0.5 | 0.5 | 0.5 | 0.5 | 0.5 | 0.5 |
| Thickness | | | | | | |
| (μm) | | | | | | |
| Stability | good | goug | gsw | good | good | good |
| Connection | good | good | good | good | good | good |
| Reliability | | | | | | |

TABLE 11

| | Comparative Examples | | | | | | | |
|---|---|---|---|---|---|---|---|---|
| | 30 | 31 | 32 | 33 | 34 | 35 | 38 | 37 |
| Base Material | Cu | Al—Cu | Cu | Cu | Cu | Al—Cu | Al—Cu | Al—Cu |
| Layer | | | | | | | | |
| Catalytic Metal | — | — | Ag | Pd | Au | Ag | Pd | Au |
| Sn Plating Bath | E | E | E | E | E | E | E | E |
| Surface Layer | unprecipitated | unprecipitated | 0.4 | 0.4 | 0.4 | 0.4 | 0.4 | 0.4 |
| Thickness (μm) | | | | | | | | |
| Stability | good | good | good | good | good | good | good | good |
| Connection | poor | poor | poor | poor | poor | poor | poor | poor |
| Reliability | | | | | | | | |

TABLE 12

| | Comparative Examples | | | | | | |
|---|---|---|---|---|---|---|---|
| | 38 | 39 | 40 | 41 | 42 | 43 | 44 |
| Base Material | Cu | Cu | Cu | Al—Cu | Al—Cu | Al—Cu | Cu |
| Layer | | | | | | | |
| Catalytic | Ag | Pd | Au | Ag | Pd | Au | Ag |
| Metal | | | | | | | |
| Sn Plating | H | H | H | H | H | H | H |
| Bath | | | | | | | |
| Surface Layer | 0.1 | 0.1 | 0.1 | 0.1 | 0.1 | 0.1 | 0.5 |
| Thickness | | | | | | | |
| (μm) | | | | | | | |
| Stability | poor | poor | poor | poor | poor | poor | poor |
| Connection | poor | poor | poor | poor | poor | poor | good |
| Reliability | | | | | | | |

TABLE 13

| | Comparative Examples | | | | | | |
|---|---|---|---|---|---|---|---|
| | 45 | 46 | 47 | 48 | 48 | 50 | 51 |
| Base Material | Cu | Cu | Cu | Al—Cu | Al—Cu | Al—Cu | Cu |
| Layer | | | | | | | |
| Catalytic | Ag | Pd | Au | Ag | Pd | Au | Pd |
| Sn Plating | I | I | I | I | I | I | I |
| Bath | | | | | | | |
| Surface Layer | 0.1 | 0.1 | 0.1 | 0.1 | 0.1 | 0.1 | 0.5 |
| Thickness | | | | | | | |
| (μm) | | | | | | | |
| Stability | poor | poor | poor | poor | poor | poor | poor |
| Connection | poor | poor | poor | poor | poor | poor | good |
| Reliability | | | | | | | |

TABLE 14

| | Comparative Examples | | | | | | |
|---|---|---|---|---|---|---|---|
| | 52 | 53 | 54 | 55 | 56 | 57 | 58 |
| Base Material | Cu | Cu | Cu | Al—Cu | Al—Cu | Al—Cu | Cu |
| Layer | | | | | | | |
| Catalytic | Ag | Pd | Au | Ag | Pd | Au | Au |
| Metal | | | | | | | |
| Sn Plating | J | J | J | J | J | J | J |
| Bath | | | | | | | |
| Surface Layer | 0.1 | 0.1 | 0.1 | 0.1 | 0.1 | 0.1 | 0.5 |
| Thickness | | | | | | | |
| (μm) | | | | | | | |
| Stability | poor | poor | poor | poor | poor | poor | poor |
| Connection | poor | poor | poor | poor | poor | poor | good |
| Reliability | | | | | | | |

A method for fabricating an electronic component according to the present disclosure enables stable fabrication of a sufficiently thick Sn plating film with high connection reliability, and thus, is useful as a method for fabricating an electronic component, for example.

What is claimed is:

1. A method for fabricating an electronic component, the method comprising:
a base material layer formation step of forming a base material layer of nickel or a nickel alloy by an electroless nickel plating bath or an electroless nickel alloy plating bath on a substrate of copper, a copper alloy, aluminium, or an aluminium alloy;
a catalyst application step of applying, as a catalyst, one or more metals selected from the group consisting of gold, palladium, platinum, silver, rhodium, cobalt, tin, copper, iridium, osmium, and ruthenium, on the base material layer, and
a surface layer formation step of forming a surface layer by an electroless tin plating bath or an electroless tin alloy plating bath containing trivalent titanium as a reducing agent and pyrophosphate salt as a complexing agent,
wherein, in the surface layer formation step, a surface layer with a thickness of 0.5 μm or more is formed.

2. The method according to claim 1, wherein the electroless tin plating bath or the electroless tin alloy plating bath includes nitrogen-free organic thiol.

3. The method according to claim 1, wherein the electroless tin plating bath or the electroless tin alloy plating bath includes sulfur oxoacid.

4. The method according to claim 1, further comprising:
a titanium reduction step of reducing tetravalent titanium generated in the electroless tin plating bath or the electroless tin alloy plating bath in the surface layer formation step, to trivalent titanium by electrolization,
wherein:
in the titanium reduction step, in a reduction process tank including an anode chamber and a cathode chamber partitioned by a cation exchange membrane, a part of a plating solution in a plating tank where the step of forming the surface layer is performed is moved to the cathode chamber, and
the surface layer formation step and the titanium reduction step are performed in parallel.
